(19) United States
(12) Patent Application Publication
(10) Pub. No.: US 2026/0068128 A1
(43) Pub. Date: Mar. 5, 2026

(54) MEMORY DEVICES AND FABRICATING METHODS THEREOF

(71) Applicant: YANGTZE MEMORY TECHNOLOGIES CO., LTD., Wuhan (CN)

(72) Inventors: Yiming Ai, Wuhan (CN); He Zhang, Wuhan (CN); Yuhuan Zheng, Wuhan (CN); Chengxing Yu, Wuhan (CN); Dan Deng, Wuhan (CN)

(21) Appl. No.: 18/895,965

(22) Filed: Sep. 25, 2024

Related U.S. Application Data
(63) Continuation of application No. PCT/CN2024/116439, filed on Sep. 3, 2024.

(51) Int. Cl. H10B 12/00

(52) U.S. Cl. CPC H10B 12/33; H10B 12/05

(57) ABSTRACT

A memory device, a memory system, and a fabricating method are provided. The disclosed memory device comprises: an array of vertical transistors arranged in a lateral plane, each vertical transistor comprising: a channel structure extending vertically with respect to the lateral plane; and a drain structure comprising: a first semiconductor layer in contact with a first end of the channel structure and having a first dopant concentration and a first lattice structure, and a second semiconductor layer between the first semiconductor layer and a bit line, and having a second dopant concentration different from the first dopant concentration and a second lattice structure different from the first lattice structure.

### CROSS-REFERENCE TO RELATED APPLICATIONS

This application is a continuation of International Application No. PCT/CN2024/116439, filed on Sep. 3, 2024, which is hereby incorporated by reference in its entirety.

### TECHNICAL FIELD

The present disclosure generally relates to the field of semiconductor technology, and more particularly, to memory devices and fabricating methods thereof.

### BACKGROUND

Planar memory cells are scaled to smaller sizes by improving process technology, circuit design, programming algorithm, and fabrication process. However, as feature sizes of the memory cells approach a lower limit, planar process, and fabrication techniques become challenging and costly. As a result, memory density for planar memory cells approaches an upper limit.

A three-dimensional (3D) memory architecture can address the density limitation in planar memory cells. The 3D memory architecture includes a memory array and peripheral circuits for facilitating operations of the memory array.

### SUMMARY

One aspect of the present disclosure provides a memory device, comprising: an array of vertical transistors arranged in a lateral plane, each vertical transistor comprising: a channel structure extending vertically with respect to the lateral plane; and a drain structure comprising: a first semiconductor layer in contact with a first end of the channel structure and having a first dopant concentration and a first lattice structure, and a second semiconductor layer between the first semiconductor layer and a bit line, and having a second dopant concentration different from the first dopant concentration and a second lattice structure different from the first lattice structure.

In some implementations, the second dopant concentration is at least 1000 times greater than the first dopant concentration.

In some implementations, the first semiconductor layer is a monocrystalline silicon layer; and the second semiconductor layer is a polycrystalline silicon layer.

In some implementations, the polycrystalline silicon layer has a dopant concentration gradient increasing from a first side in contact with the first semiconductor layer to a second side in contact with the bit line.

In some implementations, the polycrystalline silicon layer comprises a uniform second dopant concentration along the vertical direction.

In some implementations, the memory device further comprises: a polycrystalline silicon seed layer between the monocrystalline silicon layer and the polycrystalline silicon layer.

In some implementations, the gate structures of each row of vertical transistors along a first lateral direction are connected with each other to form a word line.

In some implementations, the second semiconductor layers of each column of vertical transistors along a second lateral direction are connected with a same bit line.

In some implementations, the memory device further comprises: an isolation wall extending along the first lateral direction between the channel structures of adjacent two rows of vertical transistors.

In some implementations, each vertical transistor further comprises: a source structure in contact with a second end of the channel structure opposite to the first end.

In some implementations, the memory device further comprises: an array of capacitors coupled with the source structures of array of vertical transistors.

In some implementations, a first electrode of each capacitor is coupled with the source structure of a corresponding vertical structure through a source node contact; and second electrodes of array of capacitors are connected with each other to form a common electrode.

Another aspect of the disclosure provides a method of forming a memory device, comprising: forming an array of vertical transistors, comprising: forming an array of semiconductor bodies arranged in a lateral plane, each semiconductor body extending vertically with respect to the lateral plane; lightly doping first ends of the semiconductor bodies to form a first semiconductor layer; removing portions of the lightly doped first ends of the semiconductor bodies to form trenches; and forming a heavily doped second semiconductor layer in the trenches, wherein a first lattice structure of the semiconductor bodies is different from a second lattice structure of the heavily doped second semiconductor.

In some implementations, forming the array of semiconductor bodies comprises forming isolation walls along a first lateral direction to separate adjacent rows of semiconductor bodies; and forming spacer layers along a second lateral direction to separate adjacent columns of semiconductor bodies, wherein the first ends of the semiconductor bodies of each column of semiconductor bodies are connected with each other, and the trenches are formed between adjacent spacer layers.

In some implementations, forming the heavily doped second semiconductor layer comprises doping a second semiconductor layer, such that a second dopant concentration of the second semiconductor layer is at least 1000 times greater than a first dopant concentration of the first semiconductor layer.

In some implementations, forming the first semiconductor layer comprises forming a monocrystalline silicon layer; and forming the second semiconductor layer comprises forming a polycrystalline silicon layer.

In some implementations, forming the heavily doped second semiconductor layer comprises depositing a plurality of polycrystalline silicon sub-layers to form a dopant concentration gradient along the vertical direction.

In some implementations, forming the heavily doped second semiconductor layer comprises: depositing the polycrystalline silicon layer in the trenches; and doping the polycrystalline silicon layer with phosphorus to form a uniform second dopant concentration along the vertical direction.

In some implementations, forming the heavily doped second semiconductor layer comprises: forming a seed polycrystalline silicon layer on the monocrystalline silicon layer; and epitaxially growing the polycrystalline silicon layer from the seed polycrystalline silicon layer to form a dopant concentration gradient along the vertical direction.

In some implementations, forming the array of vertical transistors further comprises: forming gate structures each on a lateral side of a corresponding semiconductor bodies, wherein the gate structures of each row of vertical transistors along the first lateral direction are connected with each other to form a word line.

In some implementations, the method further comprises: forming a bit line in each trench of the drain structures of each column of vertical transistors along the second lateral direction.

In some implementations, forming the array of vertical transistors further comprises: forming a source structure at a second end of each semiconductor body opposite to the first end.

In some implementations, the method further comprises: forming an array of capacitors coupled with the source structures of array of vertical transistors.

In some implementations, forming the array of capacitors comprises: forming source node contacts on the source structures of the array of vertical transistors; forming first electrodes of the capacitors in contact with the source node contacts; forming a dielectric layer covering the first electrodes; and forming a common second electrode of array of capacitors on the dielectric layer.

Another aspect of the present disclosure provides a memory system, comprising: a memory device comprising an array of vertical transistors arranged in a lateral plane, each vertical transistor comprising: a channel structure extending vertically with respect to the lateral plane; a drain structure comprising: a first semiconductor layer in contact with a first end of the channel structure and having a first dopant concentration and a first lattice structure, and a second semiconductor layer between the first semiconductor layer and a bit line, and having a second dopant concentration different from the first dopant concentration and a second lattice structure different from the first lattice structure; and a memory controller coupled with the memory device and configured to control the memory device.

### BRIEF DESCRIPTION OF THE DRAWINGS

The accompanying drawings, which are incorporated herein and form a part of the specification, illustrate implementations of the present disclosure and, together with the description, further serve to explain the principles of the present disclosure and to enable a person skilled in the pertinent art to make and use the present disclosure.

FIG. 1 illustrates a schematic circuit diagram of a memory device including an array of memory cells each having a vertical transistor, according to some implementations of the present disclosure.

FIG. 2 illustrates a schematic plan view of an array of memory cells each including a vertical transistor in a memory device, according to various implementations of the present disclosure.

FIG. 3A illustrates a schematic side view of a cross-section of memory cells in a 3D memory device, according to some implementations of the present disclosure.

FIG. 3B illustrates a schematic side view of a cross-section of a memory device in a 3D memory device, according to some implementations of the present disclosure.

FIG. 4 illustrates a block diagram of a system having a memory device, according to some implementations of the present disclosure.

FIG. 5 illustrates a flowchart of a fabricating method for forming a 3D memory device, according to some implementations of the present disclosure.

FIGS. 6A-6B each illustrates a schematic side cross-sectional view of a 3D memory device at a certain fabricating stage of the method shown in FIG. 5, according to various implementations of the present disclosure.

FIGS. 7A-7B each illustrates a schematic side cross-sectional view of a 3D memory device at a certain fabricating stage of the method shown in FIG. 5, according to various implementations of the present disclosure.

FIGS. 8A-8B each illustrates a schematic side cross-sectional view of a 3D memory device at a certain fabricating stage of the method shown in FIG. 5, according to various implementations of the present disclosure.

FIGS. 9A-9B each illustrates a schematic side cross-sectional view of a 3D memory device at a certain fabricating stage of the method shown in FIG. 5, according to various implementations of the present disclosure.

FIGS. 10A-10B each illustrates a schematic side cross-sectional view of a 3D memory device at a certain fabricating stage of the method shown in FIG. 5, according to various implementations of the present disclosure.

The present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features as described in the present disclosures can be combined, adjusted, and modified with one another and in ways not specifically depicted in the drawings, such that these combinations, adjustments, and modifications are within the scope of the present disclosure.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations), and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layers thereupon, thereabove, and/or therebelow. A layer can include multiple layers. For example, an interconnect layer can include one or more conductors and contact layers (in which interconnect lines and/or vertical interconnect access (via) contacts are formed) and one or more dielectric layers.

Transistors are used as the switch or selecting devices in the memory cells of some memory devices, such as dynamic radon access memory (DRAM), phase-change memory (PCM), and ferroelectric DRAM (FRAM). However, the planar transistors commonly used in existing memory cells usually have a horizontal structure with buried word lines in the substrate and bit lines above the substrate. Since the source and drain of a planar transistor are disposed laterally at different locations, which increases the area occupied by the transistor. The design of planar transistors also complicates the arrangement of interconnected structures, such as word lines and bit lines, coupled to the memory cells, for example, limiting the pitches of the word lines and/or bit lines, thereby increasing the fabrication complexity and reducing the production yield. Moreover, because the bit lines and the storage units (e.g., capacitors or PCM elements) are arranged on the same side of the planar transistors (above the transistors and substrate), the bit line process margin is limited by the storage units, and the coupling capacitance between the bit lines and storage units, such as capacitors, are increased. Planar transistors may also suffer from a high leakage current as the saturated drain current keeps increasing, which is undesirable for the performance of memory devices.

To address one or more of the aforementioned issues, vertical transistors were introduced to replace the conventional planar transistors as the switch and selecting devices in a memory cell array of memory devices (e.g., DRAM, PCM, and FRAM). In the following descriptions, DRAM is used as a non-exclusive example of the present disclosure. Compared with planar transistors, the vertically arranged transistors (i.e., the drain and source are overlapped in the plan view) can reduce the area of the transistor as well as simplify the layout of the interconnect structures, e.g., metal wiring the word lines and bit lines, which can reduce the fabrication complexity and improve the yield. For example, the pitches of word lines and/or bit lines can be reduced for ease of fabrication. The vertical structures of the transistors also allow the bit lines and storage units, such as capacitors, to be arranged on opposite sides of the transistors in the vertical direction (e.g., one above and one below the transistors), such that the process margin of the bit lines can be increased and the coupling capacitance between the bit lines and the storage units can be decreased.

However, there has been ongoing debate about ion implantation methods in vertical transistor structures. Unlike planar transistors, vertical transistors cannot rely on photolithography to define implantation regions. Bottom implantation for areas larger than 200 square nm has been particularly challenging. The current approach of bottom implantation followed by diffusion is often difficult to control. For example, backside implantation faces difficulties due to the presence of capacitors, which prevents the use of high-temperature annealing, making activation difficult and failing to eliminate IMP high-dose induced end-of-range (EOR) defects. For front-side implantation, precise control is also problematic since the implantation location depends on the depth of the vertical gate structure etch, while the diffusion position is influenced by subsequent thermal processes. The significant variation in VG etch depth leads to uncontrolled transfer of implantation depth and diffusion concentration at the drain end during the front-side implantation.

The disclosed memory devices include a novelly designed drain structure. The corresponding fabricating process involves a backside silicon recess process after a backside silicon chemical mechanical polishing (CMP) process to address the height issue of the drain ends, followed by deposition of doped polysilicon to solve the n-type doping problem of the drain ends. Laser activation is then used to mitigate end-of-range (EOR) defects and overcome the high-temperature limitation at the source, resulting in a drain structure realized by depositing doped polysilicon instead of traditional n-type doping, with precise control over the height and doping profile.

Consistent with the scope of the present disclosure, according to some implementations of the present disclosure, the memory cell array having vertical transistors each including a semiconductor body extending in a vertical direction, and a gate structure beside the semiconductor structure. In some implementations, the word lines and bit lines connected to the vertical transistors are arranged along a first lateral direction and a second lateral direction, respectively. Each of the semiconductor bodies of the array of vertical transistors extends along a vertical direction. By using such an arrangement, memory area efficiency can be increased. Further, the memory cell array and the peripheral circuits can be formed separately on different wafers, such that the fabricating processes of the memory cell array and the peripheral circuits do not affect each other, and the memory area efficiency can be further increased. Due to the particularity of the structure and the strict requirements of alignment, the bit lines are formed in a very small size, and an air gap is formed between adjacent bit lines to reduce the resistance capacitor delay (RC delay) effect and to improve the performance of the device.

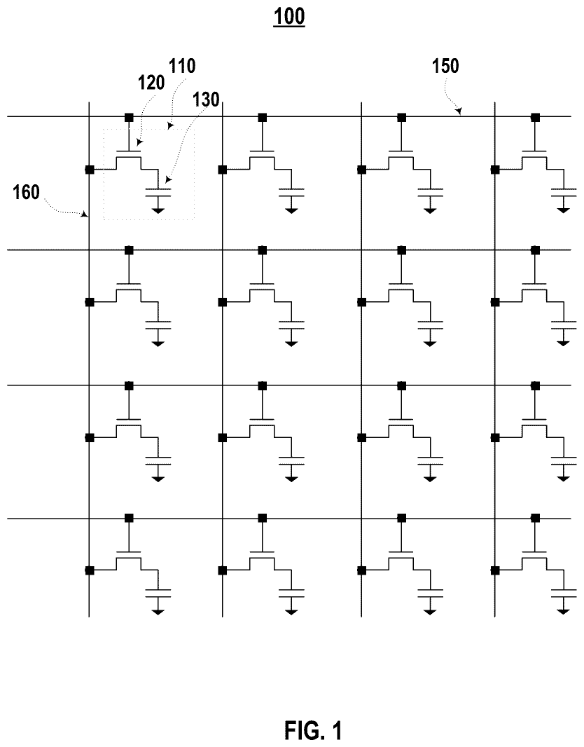

FIG. 1 illustrates a schematic diagram of a memory device 100 having an array of memory cells each having a vertical transistor, according to some implementations of the present disclosure. Memory device 100 can include a memory cell array in which each memory cell 110 includes a vertical transistor 120 and a storage unit coupled to vertical transistor 120. In some implementations as shown in FIG. 1, the memory cell array is a DRAM cell array, and the storage unit is a capacitor 130 for storing charge as the binary information stored by the respective DRAM cell. In some other implementations not shown in the figures, the memory cell array is a PCM cell array, and the storage unit can be a PCM element (e.g., including chalcogenide alloys) for storing binary information of the respective PCM cell based on the different resistivities of the PCM element in the amorphous phase and the crystalline phase. In some implementations not shown in the figures, the memory cell array is a FRAM cell array, and the storage unit can be a ferroelectric capacitor for storing binary information of the respective FRAM cell based on the switch between two polarization states of ferroelectric materials under an external electric field.

As shown in FIG. 1, memory cells 110 can be arranged in a two-dimensional (2D) array having rows and columns. Memory device 100 can include word lines 150 coupling the memory cell array to peripheral circuits for controlling the switch of vertical transistors 120 in memory cells 110 located in a row, as well as bit lines 160 coupling the memory cell array to peripheral circuits for sending data to and/or receiving data from memory cells 110 located in a column. That is, each word line 150 is coupled to a respective row of memory cells 110, and each bit line 160 is coupled to one or more respective logic columns of memory cells 110. In some implementations, the gate of vertical transistor 120 is coupled to word line 150, one of the source and the drain of vertical transistor 120 is coupled to bit line 160, the other one of the source and the drain of vertical transistor 120 is coupled to one electrode of capacitor 130, and the other electrode of capacitor 130 is coupled to the ground.

Consistent with the scope of the present disclosure, vertical transistors 120, such as vertical metal-oxide-semiconductor field-effect transistors (MOSFETs), can replace the conventional planar transistors as the pass transistors of memory cells 110 to reduce the area occupied by the pass transistors, the coupling capacitance, as well as the interconnect routing complexity, as described below in detail.

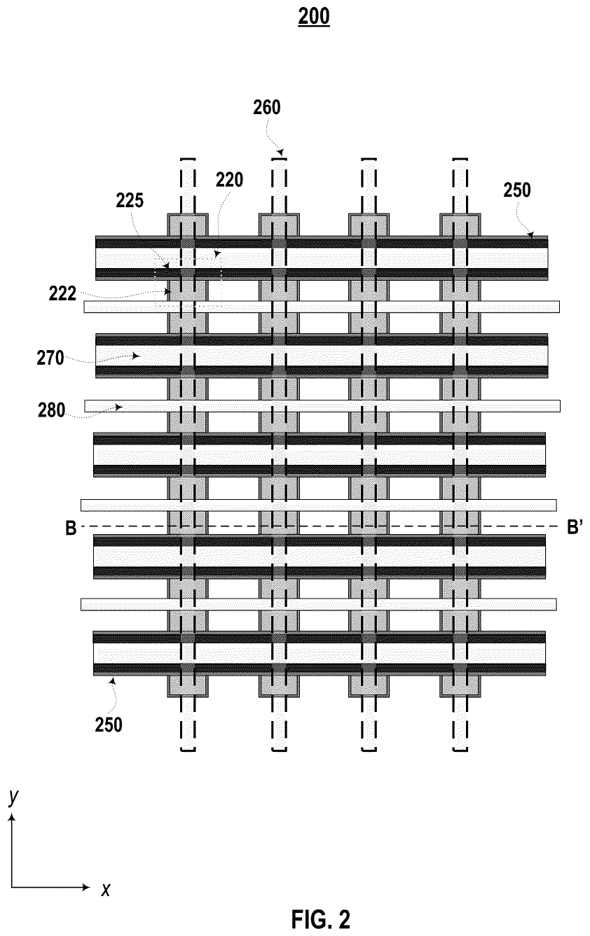

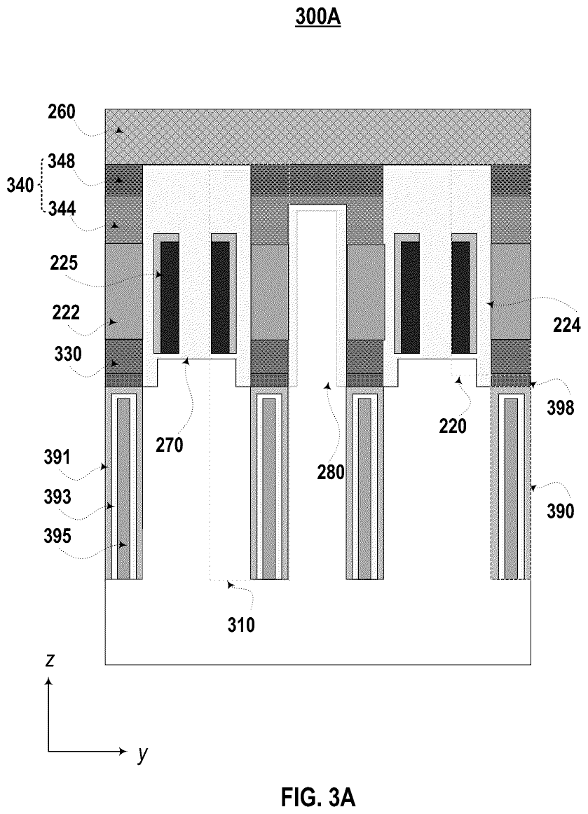

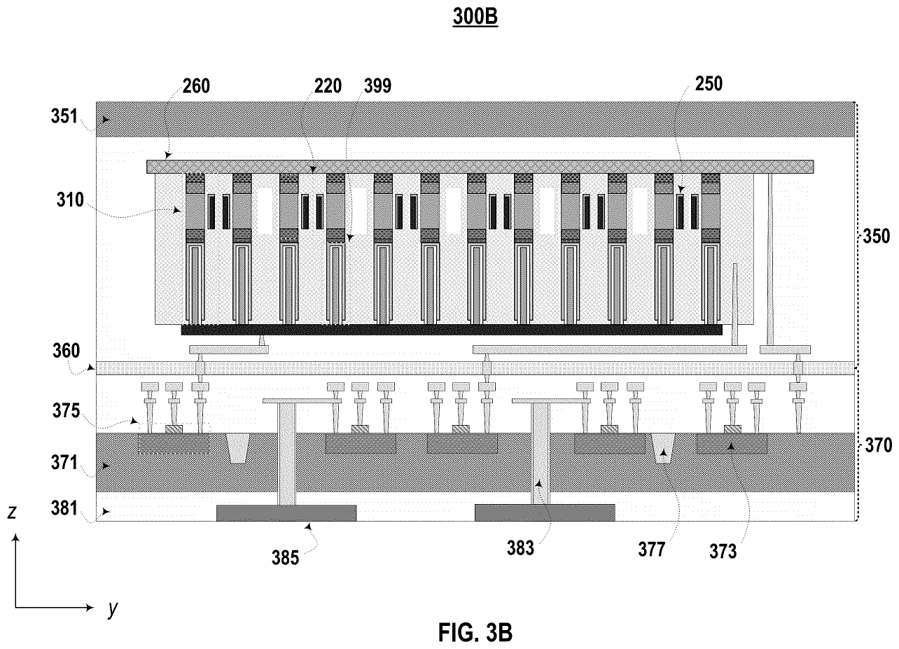

FIG. 2 illustrates a schematic plan view of an array of memory cells each including a vertical transistor in a memory device, according to various implementations of the present disclosure. FIG. 3A illustrates a schematic side view of a cross-section of memory cells in 3D memory devices, according to some implementations of the present disclosure. FIG. 3B illustrates a schematic side view of a cross-section of a memory device including the memory cells, according to some implementations of the present disclosure. It is noted that FIG. 3A illustrates a cross-sectional side view of a column of memory cells along one bit line 260 in the y-z plane.

As shown in FIG. 2, memory device 200 can include a plurality of word lines 250 each extending in a first lateral direction (the x-direction, referred to as the word line direction). Memory device 200 can also include a plurality of bit lines 260 each extending in a second lateral direction perpendicular to the first lateral direction (the y-direction, referred to as the bit line direction). It is understood that FIG. 2 does not illustrate cross-section views of memory device 200 in the same lateral plane, and word lines 250 and bit lines 260 may be formed in different lateral planes for ease of routing, as described below in detail.

As shown in FIG. 3A, in some implementations, each memory cell 310 includes a storage unit 390 and a vertical transistor 220 having a semiconductor body 222 and a gate structure 225. Each row of vertical transistors 220 is aligned along the first lateral direction (i.e., x-direction), and the gate structures 225 of each row of vertical transistors 220 are connected with each other to form a word line 250 extending along the first lateral direction (i.e., the x-direction). In some implementations, the bit lines 260 extend in parallel along the second lateral direction (i.e., the y-direction) and are connected with a column of vertical transistors 220.

As shown in FIG. 3A, semiconductor body 222 can extend in the vertical direction (i.e., z-direction) perpendicular to the first and second lateral directions. Different from planar transistors in which the active regions are formed in the substrates, vertical transistor 220 includes a semiconductor body 222 extending vertically (i.e., in the z-direction). It is understood that semiconductor body 222 may have any suitable 3D shape, such as a polyhedron shape or a cylinder shape. That is, the cross-section of semiconductor body 222 in the plan view (e.g., in the x-y plane) can have a square shape, a rectangular shape (or a trapezoidal shape), a circular shape, a partial circular shape, an oval shape, a partial oval shape, or any other suitable shapes.

In some implementations as shown in FIG. 2, semiconductor bodies 222 between adjacent vertical transistors 220 along the second lateral direction (y-direction) can be laterally separated by first spacers 270 or second spacers 280. The plurality of first spacers 270 and second spacers 280 extend in parallel along the first lateral direction (i.e., x-direction), and are alternatively arranged along the second lateral direction (i.e., y-direction).

In some implementations as shown in FIGS. 2 and 3, each vertical transistor 220 includes a gate structure 225 located at one side of the semiconductor body 222. The gate structure 225 of adjacent vertical transistors 220 in the first lateral direction (i.e., the x-direction) are continuous, e.g., parts of a continuous conductive layer having the gate structures 225. That is, multiple gate structures 225 of a row of vertical transistors 220 can be connected with each other and extend along the first lateral direction to form a word line 250 of the row of vertical transistors 220.

The two word lines 250 of two adjacent rows of vertical transistors 220 can be embedded in a same first spacer 270 separating the two adjacent rows of vertical transistors 220, as shown in FIG. 2. Gate structures 225 can include any suitable conductive materials, such as polysilicon, metals (e.g., tungsten (W), copper (Cu), aluminum (Al), etc.), metal compounds (e.g., titanium nitride (TiN), tantalum nitride (TaN), etc.), or silicides. For example, gate structure 225 may include doped polysilicon, i.e., a gate poly. In some implementations, gate structure 225 includes multiple conductive layers, such as a W layer over a TiN layer. In some implementations, a gate dielectric 224 is laterally between gate structure 225 and the semiconductor body 222. Gate dielectric 224 can include any suitable dielectric materials, such as silicon oxide, silicon nitride, silicon oxynitride, or high-k dielectrics. For example, gate dielectric 224 may include silicon oxide, i.e., gate oxide.

In some implementations, the plurality of first spacers 270 and second spacers 280 can include any suitable dielectric material, such as silicon oxide. In some implementations, each of the plurality of first spacers 270 and second spacers 280 can further include one or more air gaps embedded in the dielectric material. As described below with respect to the fabrication process, the air gaps may be formed due to the relatively small pitches of word lines 250 (and rows of vertical transistors 220) along the second lateral direction. On the other hand, the relatively large dielectric constant of air in air gaps (e.g., about four times the dielectric constant of silicon oxide) can improve the insulation effect between word lines 250 (and rows of vertical transistors 220) compared with some dielectrics (e.g., silicon oxide).

As shown in FIG. 3A, each vertical transistor 220 can include a source 330 and a drain 340 (S/D, dope regions, a.k.a., source electrode and drain electrode) formed at the two ends of semiconductor body 222 in the vertical direction (the z-direction), respectively. In each vertical transistor 220, the source 330 and drain 340 can be separated at two ends of the semiconductor body 222 in the vertical direction (the z-direction). The source 330 and/or the drain 340 can be doped with any suitable P-type dopants, such as boron (B) or Gallium (Ga), or any suitable N-type dopants, such as phosphorus (P) or arsenic (As). In some implementations, the source 330 can be lightly doped. The drain 340 can include a first semiconductor layer 344 having a first dopant concentration, and a second semiconductor layer 348 having a second dopant concentration different from the first dopant concentration. In some implementations, the second dopant concentration is at least 1000 times greater than the first dopant concentration, and a transition layer between the first semiconductor layer 344 and the second semiconductor layer 348 can be less than 3 nm. In some implementations, the second semiconductor layers 348 of the drains 340 of each column of vertical transistors along the second lateral direction (i.e., the y-direction) are connected with a same bit line 260.

In some implementations, the bit line can be heavily doped semiconductor material with a same type of dopant with the second semiconductor layer 348 and having the second dopant concentration. In some implementations, each bit line 260 can have a multi-layer structure (not shown), such as a silicide sub-layer and a metal sub-layer. For example, the silicide sub-layer can include any suitable metal silicide material and be in direct contact with the second semiconductor layer 348. The metal sub-layer can include any suitable metal material, such as W, Cu, Al, etc. In some other implementations, each bit line 260 can include a single silicide layer in direct contact with the second semiconductor layer 348.

In some implementations, the first semiconductor layer 344 has a first lattice structure, and the second semiconductor layer 348 has a second lattice structure different from the first lattice structure. For example, the first semiconductor layer 344 is a monocrystalline silicon layer, and the second semiconductor layer 348 is a polycrystalline silicon layer. In some implementations, the polycrystalline silicon layer comprises a uniform second dopant concentration along the vertical direction (i.e., the z-direction). In some other implementations, the polycrystalline silicon layer has a dopant concentration gradient increasing from a lower side to an upper side along the vertical direction (i.e., the z-direction).

In some implementations, the second semiconductor layer 348 is formed by an n-type doped polysilicon depositing process with a phosphine treatment. For example, phosphine (PH₃) gas is used as a precursor for phosphorus doping in polysilicon to introduce phosphorus atoms into the polysilicon material, creating n-type regions by donating electrons to the polysilicon material. This fabricating process allows for high doping concentrations and uniformity, as well as precise control over the doping profile. It is noted that, the second semiconductor layer 348 can be formed by a single depositing process to form a uniform doping concentration along the vertical direction, or can be formed by a series of repeated depositing processes to form a dopant concentration gradient along the vertical direction. In some other implementations, the second semiconductor layer 348 can be formed by an epitaxial growth process. For example, a polycrystalline silicon seed layer (not shown) can be formed on the first semiconductor layer 344 (i.e., monocrystalline silicon layer), and the second semiconductor layer 348 (i.e., polycrystalline silicon layer) can be epitaxially grown from the polycrystalline silicon seed layer. As another example, the second semiconductor layer 348 can be doped monocrystalline silicon formed by epitaxial growth directly from the first semiconductor layer 344 (i.e., monocrystalline silicon layer).

In some implementations, gate structure 225 is formed vertically, corresponding to the portion of the semiconductor body 222 between the source 330 and drain 340. As a result, the channel of the vertical transistor 220 can be formed in semiconductor body 222 vertically between the source 330 and drain 340 when a gate voltage applied to the gate structure 225 is above the threshold voltage of the vertical transistor 220. It is also noted that memory device 200 can include single-gate transistors as shown in FIGS. 2 and 3. That is, gate structure 225 may be in contact with a single side of semiconductor body 222. In some other implementations not shown, the disclosed memory device can include multi-gate vertical transistors, such as double-gate vertical transistors (i.e., dual-side gate vertical transistors), tri-gate vertical transistors (i.e., tri-side gate vertical transistors), and all-around-gate (GAA) vertical transistors.

As shown in FIG. 3A, the source 330 of each vertical transistor 220 can be coupled to a storage unit 390 (e.g., a capacitor) through a source node contact (SNC) 398. In some implementations, the storage unit 390 can include any devices that are capable of storing binary data (e.g., 0 and 1), including but not limited to, capacitors for DRAM cells and FRAM cells, and PCM elements for PCM cells. In some implementations, each vertical transistor 220 controls the selection and/or the state switch of the respective storage unit 390 coupled to vertical transistor 220.

In some implementations, the storage unit 390 is a capacitor. It is understood that the capacitor may include any suitable structure and configuration, such as a planar capacitor, a stack capacitor, a multi-fins capacitor, a cylinder capacitor, a trench capacitor, or a substrate-plate capacitor. In some implementations, the capacitor includes a first electrode 391 coupled with the source 330 of vertical transistor 220 by SNC 398. The capacitor can also include a capacitor dielectric 393 in contact with the first electrode 391, and a second electrode 395 in contact with the capacitor dielectric 393. That is, the capacitor can be a vertical capacitor in which two electrodes 391, 395 and the capacitor dielectric 393 in-between extend vertically (in the z-direction), and the capacitor dielectric 393 can be sandwiched between the two electrodes 391, 395. In some implementations, each first electrode 391 can be coupled to the source 330 of a respective vertical transistor 220 in the same DRAM cell, while all second electrodes 395 can be parts of a common plate (not shown) coupled to a reference voltage, e.g., a common ground. In some implementations, the capacitor dielectric 393 includes dielectric materials, such as silicon oxide, silicon nitride, or high-k dielectrics including, but not limited to, Al₂O₃, HfO₂, Ta₂O₅, ZrO₂, TiO₂, or any combination thereof. In some implementations, the two electrodes 391, 395 can include conductive materials including, but not limited to, W, Co, Cu, Al, TiN, TaN, polysilicon, silicides, or any combination thereof.

As shown in FIG. 3B, the memory cells 310 can be formed in a memory array structure 350 which is included in a memory device 300B. In some implementations, the memory array structure 350 includes one or more memory cell arrays provided in the form of one or more arrays of memory cells 310 on a substrate 351. Each memory cell array can be an array of 1T1C DRAM cells each consisting of one vertical transistor 220 and one capacitor 399, as described above in FIG. 3A. In some implementations, the memory array structure 350 can further include one or more first interconnect layers including first interconnect structures to electrically connect the word lines 250, the bit lines 260, the electrodes of capacitors 399, etc., to transfer electrical signals. In some implementations, the one or more first interconnect layers can include lateral interconnect lines and vertical interconnect access (VIA) contacts. In some implementations, as shown in FIG. 3B, the one or more first interconnect layers can also include local interconnects, such as bit line contacts, word line contacts, and capacitor contacts.

In some implementations, the memory device 300B further comprises a peripheral circuit structure 370 including a plurality of transistors 375 (e.g., planar transistors and/or semiconductor transistors, not shown) formed on or in a semiconductor layer 371. Trench isolations 377 (e.g., shallow trench isolations (STIs)) and doped regions 373 (e.g., wells, sources, and drains of transistors) can be formed on or in the semiconductor layer 371. The transistors 375 can form one or more peripheral circuits including any suitable circuits for facilitating the operations of the or more arrays of memory cells 310 by applying and sensing voltage signals and/or current signals through word lines 250 and bit lines 260 to and from each memory cell 310. The one or more peripheral circuits can include various types of peripheral circuits formed using CMOS technologies. In some implementations, the peripheral circuit structure 370 can include one or more second interconnect layers including second interconnect structures to electrically connect the transistors 375 to transfer electrical signals. In some implementations, the one or more second interconnect layers can include lateral interconnect lines and VIA contacts. In some implementations, as shown in FIG. 3B, one or more second interconnection structures 383 can extend through the semiconductor layer 371. In some implementations, the peripheral circuit structure 370 can further include a pad-out layer 381 including pad contacts 385.

In some implementations, the memory array structure 350 and the peripheral circuit structure 370 can be bonded together at the bonding interface 360. The bonding interface 360 can be an interface between the memory array structure 350 and the peripheral circuit structure 370 formed by any suitable bonding technologies, such as hybrid bonding, anodic bonding, fusion bonding, transfer bonding, adhesive bonding, eutectic bonding, to name a few. The first interconnection structures of the one or more first interconnect layers can be joined with the second interconnection structures of the one or more second interconnect layers at the bonding interface 360 to couple the transistors 375 with the memory cells 310 through bit lines 260, word lines 250, and any other suitable metal wirings.

As used herein, the term “interconnection structures” and/or “interconnects” can broadly include any suitable types of interconnects, such as middle-end-of-line (MEOL) interconnects and back-end-of-line (BEOL) interconnects. The one or more first and second interconnect layers can further include one or more interlayer dielectric (ILD) layers (also known as “intermetal dielectric (IMD) layers”) in which the interconnect lines and VIA contacts can form. That is, the one or more first and second interconnect layers can include interconnect lines and VIA contacts in multiple ILD layers. The interconnects in the one or more first and second interconnect layers can include conductive materials including, but not limited to, W, Co, Cu, Al, doped silicon, silicide, or any combination thereof. The ILD layers can be formed with dielectric materials including, but not limited to, silicon oxide, silicon nitride, silicon oxynitride, low-k dielectrics, or any combination thereof.

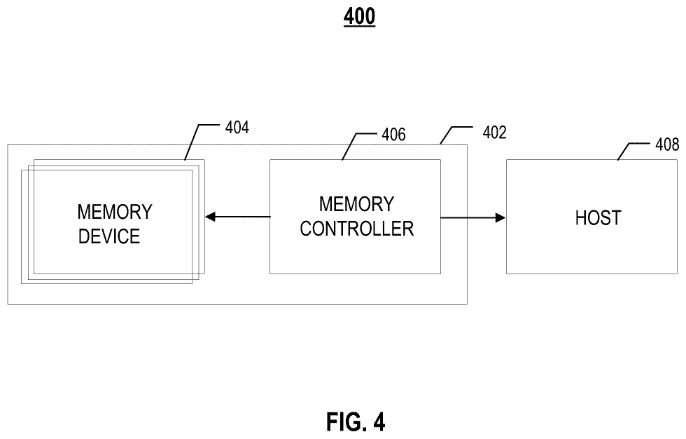

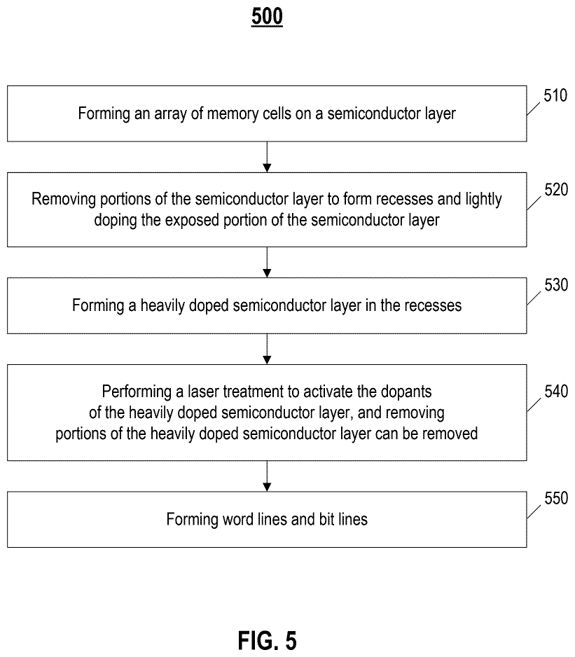

FIG. 4 illustrates a block diagram of a system 400 having a memory device, according to some implementations of the present disclosure. System 400 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 5, system 400 can include a host 408 and a memory system 402 having one or more memory devices 404 and a memory controller 406. Host 408 can be a processor of an electronic device, such as a central processing unit (CPU), or a system-on-chip (SoC), such as an application processor (AP). Host 408 can be configured to send or receive the data to or from memory devices 404. Memory device 404 can be any memory devices disclosed herein, such as memory device 100. In some implementations, memory device 404 includes an array of memory cells shown in 200/300A/300B/400A each including a vertical transistor, as described above in detail.

Memory controller 406 is coupled to memory device 404 and host 408 and is configured to control memory device 404, according to some implementations. Memory controller 406 can manage the data stored in memory device 404 and communicate with host 408. Memory controller 406 can be configured to control operations of memory device 404, such as read, write, and refresh operations. Memory controller 406 can also be configured to manage various functions with respect to the data stored or to be stored in memory device 404 including, but not limited to refresh and timing control, command/request translation, buffer and schedule, and power management. In some implementations, memory controller 406 is further configured to determine the maximum memory capacity that the computer system can use, the number of memory banks, memory type and speed, memory particle data depth and data width, and other important parameters. Any other suitable functions may be performed by memory controller 406 as well. Memory controller 406 can communicate with an external device (e.g., host 408) according to a particular communication protocol. For example, memory controller 406 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

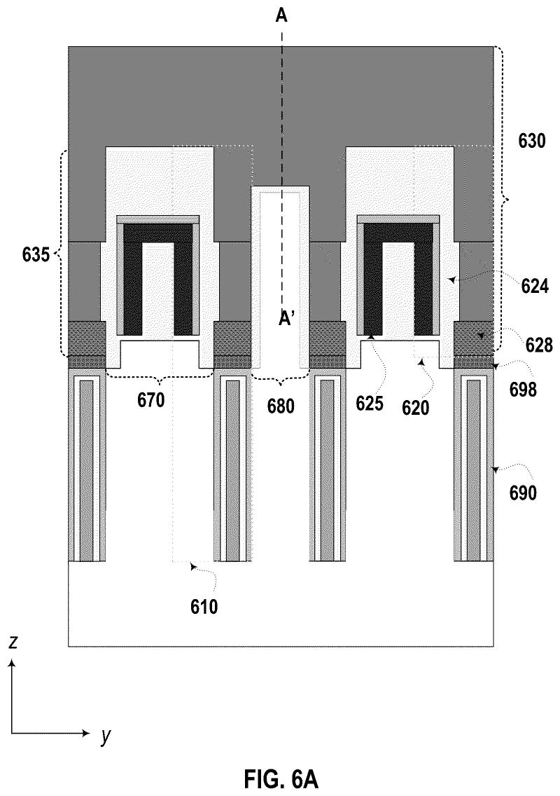

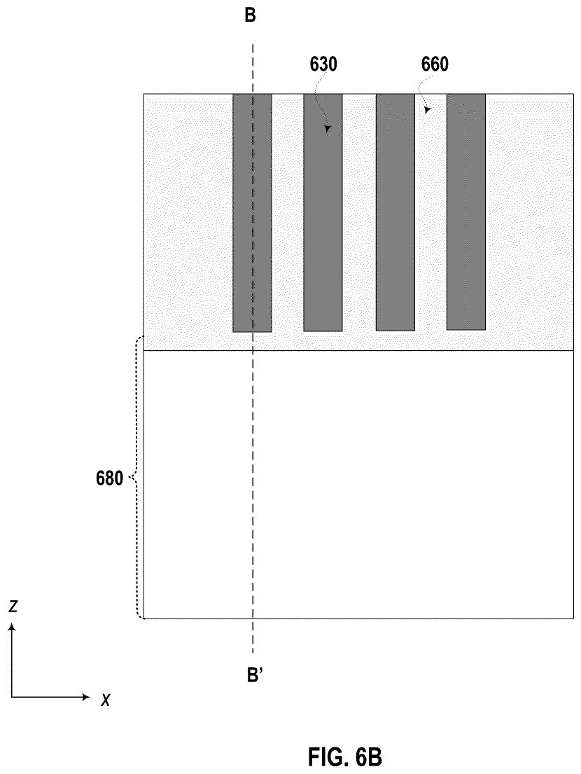

FIG. 5 illustrates a flowchart of a fabricating method 500 for forming a 3D memory device including vertical transistors, such as memory device 300 described above in connection with FIG. 3, according to some implementations of the present disclosure. FIGS. 6A-8B, 7A-7B, 8A-8B, 9A-9B, and 10A-10B illustrate schematic side cross-sectional views of a 3D memory device at certain fabricating stages of the method 500 shown in FIG. 5, according to various implementations of the present disclosure. It is understood that the operations shown in method 500 are not exhaustive and that other operations can be performed as well before, after, or between any of the illustrated operations. Further, some of the operations may be performed simultaneously, or in a different order than shown in FIG. 5.

As shown in FIG. 5, method 500 can start at operation 510, in which an array of memory cells can be formed on a semiconductor layer. FIG. 6A illustrates a schematic side cross-sectional view of the array of memory cells along a bit line in y-z plane after operation 510 of method 500. FIG. 6B illustrates a schematic side cross-sectional view of the 3D structure in x-z plane after operation 510 of method 500. It is noted that, FIG. 6B illustrates the structure along AA′ line shown in FIG. 6A, while FIG. 6A illustrates the structure along BB′ line shown in FIG. 6B. It is also noted that some components shown in FIG. 6A are not shown in FIG. 6B.

In some implementations as shown in FIG. 6A, the array of memory cells 610 can include an array of vertical transistors 620 and an array of capacitors 690. Each vertical transistor 620 can include a semiconductor pillar 635 extending vertically (in the z-direction) and have any suitable 3D shape, such as polyhedron shapes or a cylinder shape. That is, the cross-section of each semiconductor pillar 635 in the plan view (e.g., in the x-y plane) can have a square shape, a rectangular shape (or a trapezoidal shape), a circular shape, an oval shape, or any other suitable shapes.

In some implementations, forming the array of semiconductor pillars 635 can include forming a plurality of parallel first spacers 670 and second spacers 680 extending along the first lateral direction (i.e., the x-direction), as shown in FIG. 6A, and a plurality of parallel third spacers 660 extending along the second lateral direction (i.e., the y-direction), as shown in FIG. 6B. In some implementations, a lithography process is performed to pattern a plurality of first, second, and third trenches using an etch mask (e.g., a photoresist mask and/or a hard mask), and one or more dry etching and/or wet etching processes, such as RIE, are performed to etch the plurality of first, second, and third trenches in a portion of a semiconductor layer 630. Then, the first spacers 670, second spacers 680, and third spacers 660 can be formed by depositing a dielectric material, such as silicon oxide, to fill the third trenches, using a thin film deposition process including, but not limited to, CVD, PVD, ALD, or any combination thereof. After the lithography process, upper remaining portions of the semiconductor layer 630 are divided into multiple semiconductor walls extending along the second lateral direction (i.e., the y-direction) and separated by the third spacers 660, as shown in FIG. 6B. Lower remaining portions of the semiconductor layer 630 are divided into multiple semiconductor pillars 635 each extending along the vertical direction (i.e., the z-direction) and separated by the first spacers 670, second spacers 680, and third spacers 660, as shown in FIG. 6A.

As shown in FIG. 6A, forming the array of memory cells 610 can further include forming conductive structures 625 embedded in each first spacer 670. In some implementations, each conductive structure 625 can be isolated from an adjacent row of semiconductor pillars 635 by a gate dielectric layer 624. The conductive structure 625 can be used as the gate structure of each vertical transistor 620. The conductive structures 625 of a row of vertical transistors 620 extending along the first lateral direction can be connected with each other to form a word line. As shown in FIG. 6A, forming the array of memory cells 610 can further include doping an end of each semiconductor pillar 635 by ion implantation and/or thermal diffusion to form a doped region 628 as a source of the vertical transistor 620. As shown in FIG. 6A, forming the array of memory cells 610 can further include forming the plurality of capacitors 690 each being electrically coupled with the doped region 628 of each semiconductor pillar 635 via SNC 698.

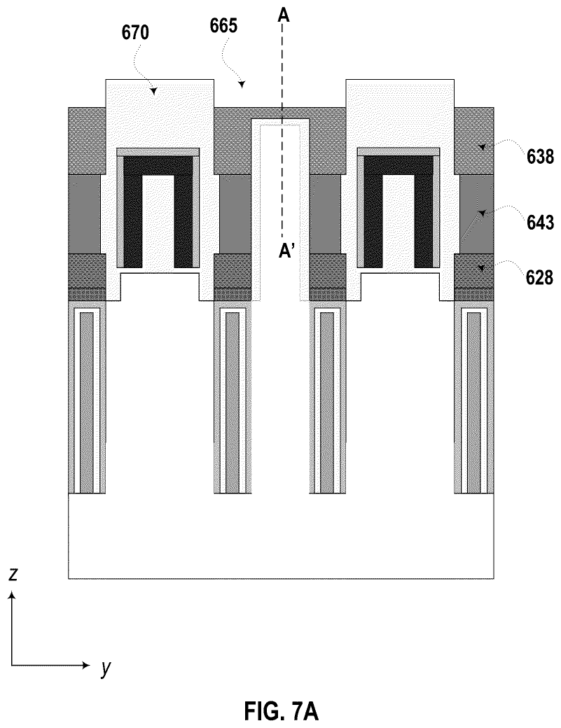

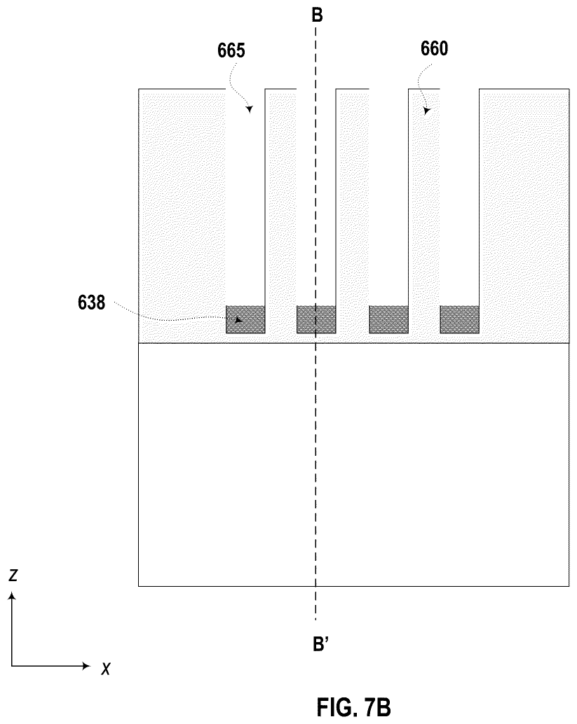

Referring back to FIG. 5, method 500 can proceed to operation 520, in which portions of the semiconductor layer can be removed, and the exposed portion of the semiconductor layer can be lightly doped. FIG. 7A illustrates a schematic side cross-sectional view of the array of memory cells along y-z plane after operation 520 of method 500. FIG. 7B illustrates a schematic side cross-sectional view of the 3D structure in x-z plane after operation 520 of method 500. It is noted that, FIG. 7B illustrates the structure along AA′ line shown in FIG. 7A, while FIG. 7A illustrates the structure along BB′ line shown in FIG. 7B. It is also noted that some components shown in FIG. 7A are not shown in FIG. 7B.

As shown in FIGS. 7A and 7B, portions of semiconductor layer 630 can be removed from the back side (top side in FIGS. 7A and 7B) by any suitable process, such as a wet etching process. As such, recesses 665 can be formed between adjacent first spacers 670 and third spacers 660. The exposed portions of the semiconductor layer 630 in the recesses 665 can be lightly doped by ion implantation and/or thermal diffusion to form first semiconductor layer 638, as part of the drain structure of the vertical transistors 620. The remaining undoped region in semiconductor pillars 635 can be used as the channel 643 of the vertical transistors 620.

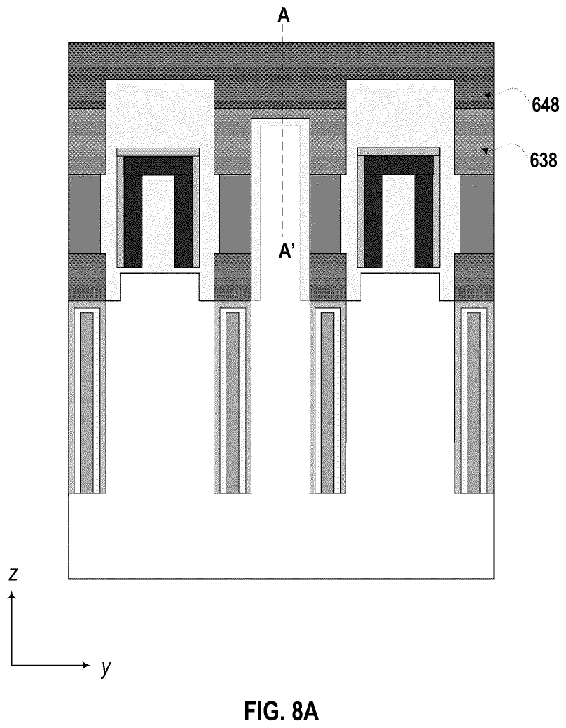

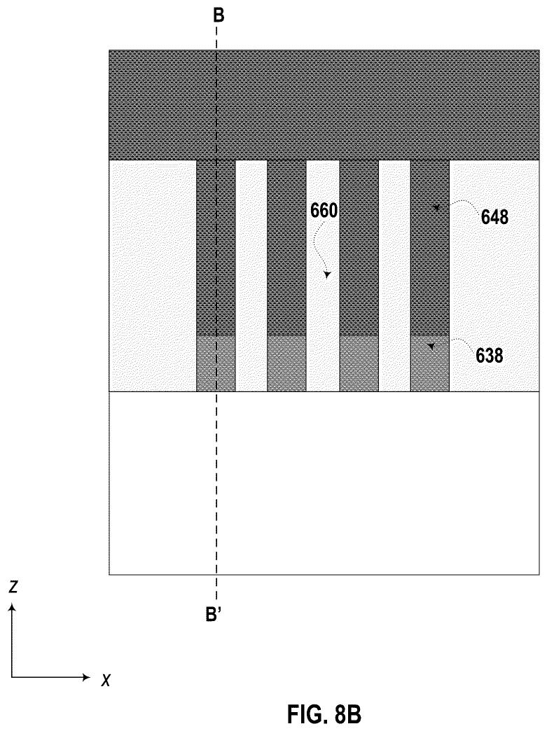

Referring back to FIG. 5, method 500 can proceed to operation 530, in which a heavily doped semiconductor layer can be formed in the recesses. FIG. 8A illustrates a schematic side cross-sectional view of the array of memory cells along y-z plane after operation 530 of method 500. FIG. 8B illustrates a schematic side cross-sectional view of the 3D structure in x-z plane after operation 530 of method 500. It is noted that, FIG. 8B illustrates the structure along the AA′ line shown in FIG. 8A, while FIG. 8A illustrates the structure along BB′ line shown in FIG. 8B. It is also noted that some components shown in FIG. 8A are not shown in FIG. 8B.

As shown in FIGS. 8A and 8B, a heavily doped semiconductor layer 648 can be formed to fill the recesses 665. In some implementations, the heavily doped semiconductor layer 648 can be doped with any suitable P-type dopants, such as B or Ga, or any suitable N-type dopants, such as P or As. In some implementations, heavily doped semiconductor layer 648 has a uniform dopant concentration along the vertical direction (i.e., the z-direction). The dopant concentration of the heavily doped semiconductor layer 648 can be at least 1000 times greater than the dopant concentration of the first semiconductor layer 638. In some other implementations, the heavily doped semiconductor layer 648 has a dopant concentration gradient increasing from a lower side to an upper side along the vertical direction (i.e., the z-direction).

In some implementations, the first semiconductor layer 638 has a first lattice structure, and the heavily doped semiconductor layer 648 has a second lattice structure different from the first lattice structure. For example, the first semiconductor layer 638 is a monocrystalline silicon layer, and the heavily doped semiconductor layer 648 is a polycrystalline silicon layer. In some implementations, the heavily doped semiconductor layer 648 is formed by an n-type doped polysilicon depositing process with a phosphine treatment. For example, phosphine (PH₃) gas is used as a precursor for phosphorus doping in polysilicon to introduce phosphorus atoms into the heavily doped semiconductor layer 648, creating n-type regions by donating electrons to the material. This fabricating process allows for high doping concentrations and uniformity, as well as precise control over the doping profile.

In some implementations, the heavily doped semiconductor layer 648 can be formed by a single depositing process to form a uniform doping concentration along the vertical direction, or can be formed by a series of repeated depositing processes to form a dopant concentration gradient along the vertical direction. In some other implementations, the heavily doped semiconductor layer 648 can be formed by an epitaxial growth process. For example, a polycrystalline silicon seed layer (not shown) can be formed on the first semiconductor layer 638 (i.e., monocrystalline silicon layer), and the heavily doped semiconductor layer 648 (i.e., polycrystalline silicon layer) can be epitaxially grown from the polycrystalline silicon seed layer. As another example, the heavily doped semiconductor layer 648 can be doped monocrystalline silicon formed by epitaxial growth directly from the first semiconductor layer 638 (i.e., monocrystalline silicon layer).

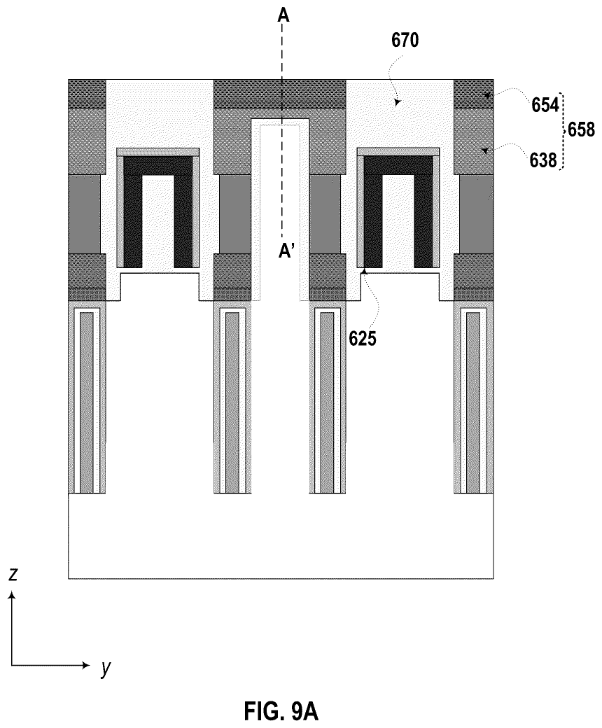

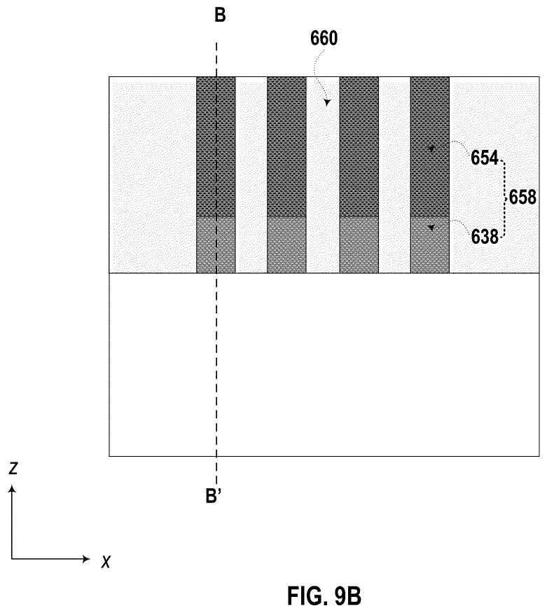

Referring back to FIG. 5, method 500 can proceed to operation 540, in which a laser treatment can be performed to activate the dopants of the heavily doped semiconductor layer, and portions of the heavily doped semiconductor layer outside of the recesses can be removed. FIG. 9A illustrates a schematic side cross-sectional view of the array of memory cells along y-z plane after operation 540 of method 500. FIG. 9B illustrates a schematic side cross-sectional view of the 3D structure in x-z plane after operation 540 of method 500. It is noted that, FIG. 9B illustrates the structure along the AA′ line shown in FIG. 9A, while FIG. 9A illustrates the structure along the BB′ line shown in FIG. 9B. It is also noted that some components shown in FIG. 9A are not shown in FIG. 9B.

In some implementations, a laser activation process can be performed to activate dopants that have been introduced into the heavily doped semiconductor layer 648. The laser activation process can electrically activate the dopants while minimizing damage to the polysilicon crystal structure of the heavily doped semiconductor layer 648. Specifically, a high-intensity laser pulse can be applied to rapidly heat the surface of the heavily doped semiconductor layer 648, causing the dopants to diffuse slightly and move into substitutional positions in the lattice without causing significant diffusion or damage to the surrounding material. Since the laser can heat the material locally and very quickly, it allows for activation without heating the entire wafer, thereby facilitating precise control over dopant profiles. Furthermore, the laser activation process requires a low thermal budget. Since the heating is very localized and brief, the surrounding areas remain relatively cool, reducing the overall thermal budget. This is beneficial for preventing unwanted diffusion of dopants and for activating dopants in structures sensitive to high temperatures.

After the laser activation process, a CMP process can be performed to remove extra portions of the heavily doped semiconductor layer 648 outside of the recesses 665, such that the top surfaces of the remaining portions of the heavily doped semiconductor layer 648 coplanar with the top surfaces of the first spacers 670 and third spacers 660, as shown in FIGS. 9A and 9B. As such, the remaining portions of the heavily doped semiconductor layer 648 in the recesses 665 form the second semiconductor layer 654. The first semiconductor layer 638 and the second semiconductor layer 654 together form the drain structure 658 of the vertical transistors 620, as shown in FIGS. 9A and 9B.

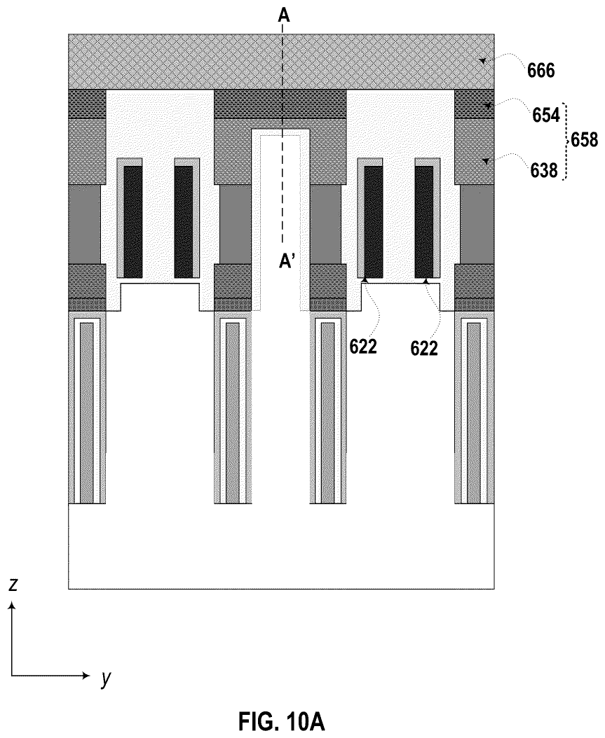

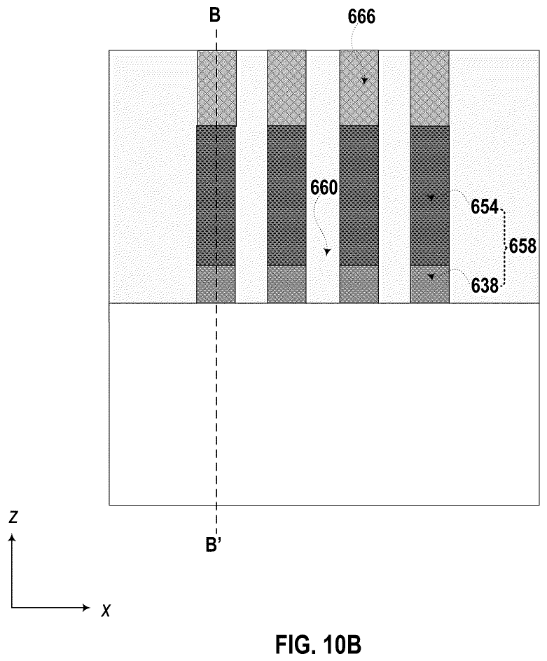

Referring back to FIG. 5, method 500 can proceed to operation 550, in which word lines and bit lines can be formed. FIG. 10A illustrates a schematic side cross-sectional view of the array of memory cells along y-z plane after operation 550 of method 500. FIG. 10B illustrates a schematic side cross-sectional view of the 3D structure in x-z plane after operation 550 of method 500. It is noted that, FIG. 10B illustrates the structure along the AA′ line shown in FIG. 10A, while FIG. 10A illustrates the structure along the BB′ line shown in FIG. 10B. It is also noted that some components shown in FIG. 10A are not shown in FIG. 9B.

As shown in FIG. 10A, in some implementations, a dry etching process, such as a punch etching process, can be performed in the first space to remove lateral portions of the conductive structure 625. The remaining vertical portions of the conductive structure 625 can be on one or more lateral sides of the channel 643 of the vertical transistors 620, and function as the gate electrode 622 of the vertical transistors 620. It is noted that, the gate electrodes 622 of a row of vertical transistors 620 along the first lateral direction (the x-direction) can be connected with each other to form a word line extending in the first lateral direction (the x-direction).

As shown in FIGS. 10A and 10B, a bit line 666 can be formed on the top surfaces of the second semiconductor layer 654, the first spacers 670, and the third spacers 660. In some implementations, the bit line 666 can have a multi layers structure. For example, a metal silicide layer can be formed on the top surfaces of the second semiconductor layer 654, the first spacers 670, and the third spacers 660. The metal silicide layer can be formed by depositing a silicon layer and a followed metal ion implantation and/or thermal diffusion to transform the silicon layer into the metal silicide layer. In some implementations, the metal silicide layer can include NiSi. Then, a metal layer, including any suitable metal material, such as W, Cu, l, etc., can be formed on the silicide layer. The metal layer and the silicide layer can form a bit line 666 extending along the second lateral direction (i.e., the y-direction). In some implementations, operation 550 further comprises forming bit line spacers (not shown) between adjacent bit lines 666 in the second lateral direction (i.e., the y-direction). In some implementations, the bit line spacers can be formed by depositing dielectrics using one or more thin film deposition processes including, but not limited to, CVD, PVD, ALD, or any combination thereof. It is understood that in some examples, the dielectrics include silicon oxide.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described implementations, but should be defined only in accordance with the following claims and their equivalents.

What is claimed is:

1. A memory device, comprising:
an array of vertical transistors arranged in a lateral plane, each vertical transistor comprising:
a channel structure extending vertically with respect to the lateral plane; and
a drain structure comprising:
a first semiconductor layer in contact with a first end of the channel structure and having a first dopant concentration and a first lattice structure, and
a second semiconductor layer between the first semiconductor layer and a bit line, and having a second dopant concentration different from the first dopant concentration and a second lattice structure different from the first lattice structure.

2. The memory device of claim 1, wherein the second dopant concentration is at least 1000 times greater than the first dopant concentration.

3. The memory device of claim 1, wherein:
the first semiconductor layer is a monocrystalline silicon layer; and
the second semiconductor layer is a polycrystalline silicon layer.

4. The memory device of claim 3, wherein:
the polycrystalline silicon layer has a dopant concentration gradient increasing from a first side in contact with the first semiconductor layer to a second side in contact with the bit line.

5. The memory device of claim 3, wherein:
the polycrystalline silicon layer comprises a uniform second dopant concentration along a vertical direction.

6. The memory device of claim 4, further comprising:
a polycrystalline silicon seed layer between the monocrystalline silicon layer and the polycrystalline silicon layer.

7. The memory device of claim 1, wherein:
gate structures of each row of vertical transistors along a first lateral direction are connected with each other to form a word line; and
the second semiconductor layers of the drain structures of each column of vertical transistors along a second lateral direction are connected with a same bit line.

8. The memory device of claim 1, further comprising:
source structures of array of vertical transistors, each of the source structure being in contact with a second end of the channel structure of a corresponding vertical transistor opposite to the first end; and
an array of capacitors coupled with the source structures of array of vertical transistors.

9. The memory device of claim 9, wherein:
a first electrode of each capacitor is coupled with the source structure of a corresponding vertical structure through a source node contact; and
second electrodes of array of capacitors are connected with each other to form a common electrode.

10. A method of forming a memory device, comprising:
forming an array of vertical transistors, comprising:
forming an array of semiconductor bodies arranged in a lateral plane, each semiconductor body extending vertically with respect to the lateral plane;
lightly doping first ends of the semiconductor bodies to form a first semiconductor layer;
removing portions of the lightly doped first ends of the semiconductor bodies to form trenches; and
forming a heavily doped second semiconductor layer in the trenches, wherein a first lattice structure of the semiconductor bodies is different from a second lattice structure of the heavily doped second semiconductor layer.

11. The method of claim 10, wherein forming the array of semiconductor bodies comprises
forming isolation walls along a first lateral direction to separate adjacent rows of semiconductor bodies; and
forming spacer layers along a second lateral direction to separate adjacent columns of semiconductor bodies,
wherein the first ends of the semiconductor bodies of each column of semiconductor bodies are connected with each other, and the trenches are formed between adjacent spacer layers.

12. The method of claim 11, wherein forming the heavily doped second semiconductor layer comprises doping a second semiconductor layer, such that a second dopant concentration of the second semiconductor layer is at least 1000 times greater than a first dopant concentration of the first semiconductor layer.

13. The method of claim 12, wherein:
forming the first semiconductor layer comprises forming a monocrystalline silicon layer; and
forming the second semiconductor layer comprises forming a polycrystalline silicon layer.

14. The method of claim 13, wherein forming the heavily doped second semiconductor layer comprises depositing a plurality of polycrystalline silicon sub-layers to form a dopant concentration gradient along a vertical direction.

15. The method of claim 13, wherein forming the heavily doped second semiconductor layer comprises:
depositing the polycrystalline silicon layer in the trenches; and
doping the polycrystalline silicon layer with phosphorus to form a uniform second dopant concentration along a vertical direction.

16. The method of claim 13, wherein forming the heavily doped second semiconductor layer comprises:
forming a seed polycrystalline silicon layer on the monocrystalline silicon layer; and
epitaxially growing the polycrystalline silicon layer from the seed polycrystalline silicon layer to form a dopant concentration gradient along a vertical direction.

17. The method of claim 10, wherein forming the array of vertical transistors further comprises:
forming gate structures each on a lateral side of a corresponding semiconductor bodies, wherein the gate structures of each row of vertical transistors along the first lateral direction are connected with each other to form a word line; and
forming a source structure at a second end of each semiconductor body opposite to the first end.

18. The method of claim 17, further comprising:
forming a bit line in each trench in contact with the second semiconductor layers of each column of vertical transistors along the second lateral direction; and
forming an array of capacitors coupled with the source structures of array of vertical transistors.

19. The method of claim 18, wherein forming the array of capacitors comprises:
forming source node contacts on the source structures of the array of vertical transistors;
forming first electrodes of the capacitors in contact with the source node contacts;
forming a dielectric layer covering the first electrodes; and
forming a common second electrode of array of capacitors on the dielectric layer.

20. A memory system, comprising:
a memory device comprising an array of vertical transistors arranged in a lateral plane, each vertical transistor comprising:
a channel structure extending vertically with respect to the lateral plane;
a drain structure comprising:
a first semiconductor layer in contact with a first end of the channel structure and having a first dopant concentration and a first lattice structure, and
a second semiconductor layer between the first semiconductor layer and a bit line, and having a second dopant concentration different from the first dopant concentration and a second lattice structure different from the first lattice structure; and
a memory controller coupled with the memory device and configured to control the memory device.
